(19) United States
(12) Patent Application Publication
(10) Pub. No.: US 2024/0204154 A1
(43) Pub. Date: Jun. 20, 2024

(54) DISPLAY DEVICE

(71) Applicant: LG Display Co., Ltd., Seoul (KR)

(72) Inventors: Sujin HAM, Seoul (KR); SungJoon MIN, Goyang-si (KR); HaeYoon JUNG, Seoul (KR); MyungSub LIM, Seoul (KR); YuRa JEONG, Seoul (KR); Heewon KIM, Hwaseong-si (KR)

(73) Assignee: LG Display Co., Ltd., Seoul (KR)

(21) Appl. No.: 18/371,992

(22) Filed: Sep. 22, 2023

(30) Foreign Application Priority Data
Dec. 15, 2022 (KR) 10-2022-0175649

(51) Int. Cl. H01L 33/62; H01L 25/075; H01L 25/16

(52) U.S. Cl. CPC H01L 33/62; H01L 25/0753; H01L 25/167

(57) ABSTRACT

A display device includes a lower substrate which is stretchable, a plurality of pixels disposed on the lower substrate, a plurality of lower connection lines disposed on the lower substrate and connected to each of the plurality of pixels, an upper substrate which is opposite to the lower substrate and is stretchable, a plurality of conductive patterns disposed below the upper substrate and connected to the plurality of pixels, respectively, and a plurality of upper connection lines disposed below the upper substrate and connected to the plurality of conductive patterns. By this configuration of the display device, the dropping of a driving voltage can be minimized.

### CROSS-REFERENCE TO RELATED APPLICATIONS

This application claims priority to Korean Patent Application No. 10-2022-0175649 filed on Dec. 15, 2022, in the Korean Intellectual Property Office, the entire disclosure of which is hereby expressly incorporated by reference into the present application.

### BACKGROUND

### Field

The present disclosure relates to a stretchable display device.

### Discussion of the Related Art

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to include personal digital assistants as well as monitors of computers and televisions. A display device with a large display area and a reduced volume and weight is being studied.

Recently, a display device which is manufactured by forming a display unit and a wiring line on a flexible substrate made of a flexible material such as plastics, can be stretchable in a specific direction and changed in various forms. Such a display device is getting attention as a next generation display device.

### SUMMARY OF THE DISCLOSURE

An object to be achieved by the present disclosure is to provide a display device which is stretchable and includes a vertical LED.

Another object to be achieved by the present disclosure is to provide a display device which minimizes drop of a driving voltage.

Still another object to be achieved by the present disclosure is to provide a display device which is capable of reducing a number of connection lines of the lower substrate.

Objects of the present disclosure are not limited to the above-mentioned objects, and other objects, which are not mentioned above, can be clearly understood by those skilled in the art from the following descriptions.

According to an aspect of the present disclosure, a display device includes a lower substrate which is stretchable; a plurality of pixels disposed on the lower substrate; a plurality of lower connection lines which is disposed on the lower substrate and is connected to each of the plurality of pixels; an upper substrate which is opposite to the lower substrate and is stretchable; a plurality of conductive patterns which is disposed below the upper substrate and is connected to the plurality of pixels, respectively; and a plurality of upper connection lines which is disposed below the upper substrate and is connected to the plurality of conductive patterns. By doing this, the dropping of a driving voltage can be minimized.

Other detailed matters of the exemplary embodiments are included in the detailed description and the drawings.

According to the present disclosure, a stable low potential voltage is supplied to the light emitting diode to ensure the luminous efficiency and the stability of the light emitting diode.

A number of connection lines on the lower substrate is reduced so that a stretching rate of the display device can be improved.

According to the present disclosure, a resistance of a conductive pattern which transmits a gate voltage is minimized to suppress the delay of the gate voltage.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view illustrating a display device according to an exemplary embodiment of the present disclosure;

FIG. 2 is an enlarged plan view of a lower substrate of a display device according to an exemplary embodiment of the present disclosure;

FIG. 3 is an enlarged plan view of an upper substrate of a display device according to an exemplary embodiment of the present disclosure;

FIG. 4 is a cross-sectional view taken along the line IV-IV′ of FIGS. 2 and 3;

FIG. 5 is an enlarged plan view of a lower substrate of a display device according to another exemplary embodiment of the present disclosure;

FIG. 6 is an enlarged plan view of an upper substrate of a display device according to another exemplary embodiment of the present disclosure;

FIG. 7 is a cross-sectional view taken along the line VII-VII′ of FIGS. 5 and 6;

FIG. 8 is an enlarged plan view of a lower substrate of a display device according to still another exemplary embodiment of the present disclosure;

FIGS. 9 and 10 are enlarged plan views of an upper substrate of a display device according to still another exemplary embodiment of the present disclosure.

FIG. 11 is a cross-sectional view taken along the line XI-XI′ of FIGS. 8 to 10; and

FIG. 12 is a cross-sectional view taken along the line XII-XII′ of FIGS. 8 to 10.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” “comprising,” etc. used herein are generally intended to allow other components to be added unless the terms are used with the term “only”. Any references to singular can include plural unless expressly stated otherwise. Further, the term “exemplary” is interchangeably used with the term “example” and has the same or similar meaning as such term.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings. All components of each display device according to all embodiments of the present disclosure are operatively coupled and configured.

A display device according to an exemplary embodiment of the present disclosure is a display device which is capable of displaying images even in a bent or extended state and is also referred to as a stretchable display device, a flexible display device and an extendable display device. As compared with the general display devices of the related art, the display device has not only a high flexibility, but also stretchability. Therefore, the user can bend or extend a display device and a shape of a display device can be freely changed in accordance with manipulation of a user. For example, when the user pulls the display device by holding ends of the display device, the display device can be extended to the pulling direction of the user. Alternatively, when the user disposes the display device on an outer surface which is not flat, the display device can be disposed to be bent in accordance with the shape of the outer surface of the wall. Further, when a force applied by the user is removed, the display device can return to its original shape.

### Stretchable Substrate and Pattern Layer

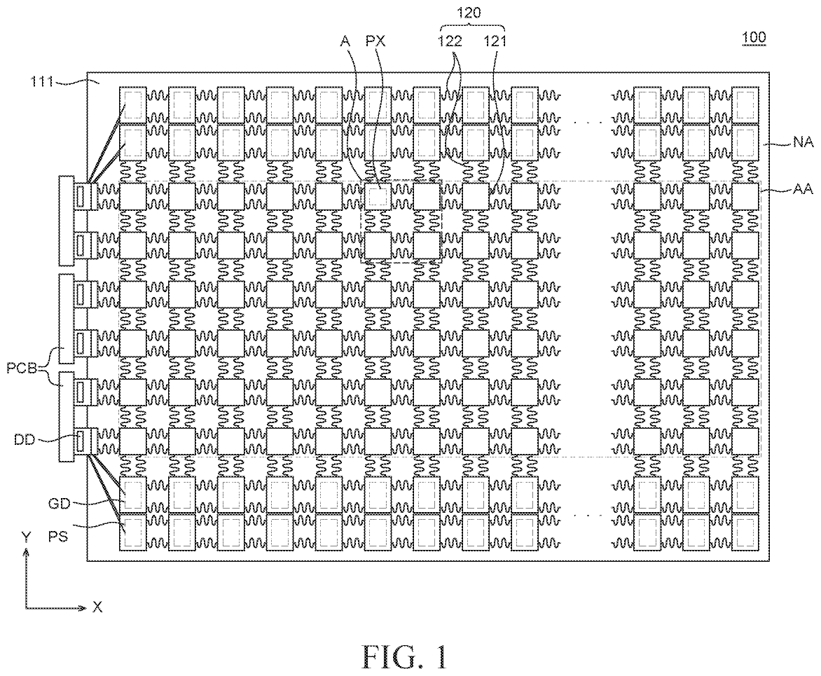

FIG. 1 is a plan view illustrating a display device according to an exemplary embodiment of the present disclosure.

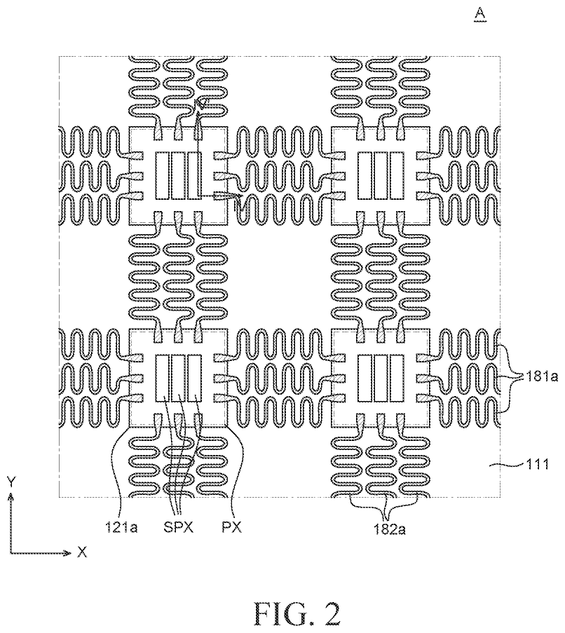

FIG. 2 is an enlarged plan view of a lower substrate 111 of a display device according to an exemplary embodiment of the present disclosure.

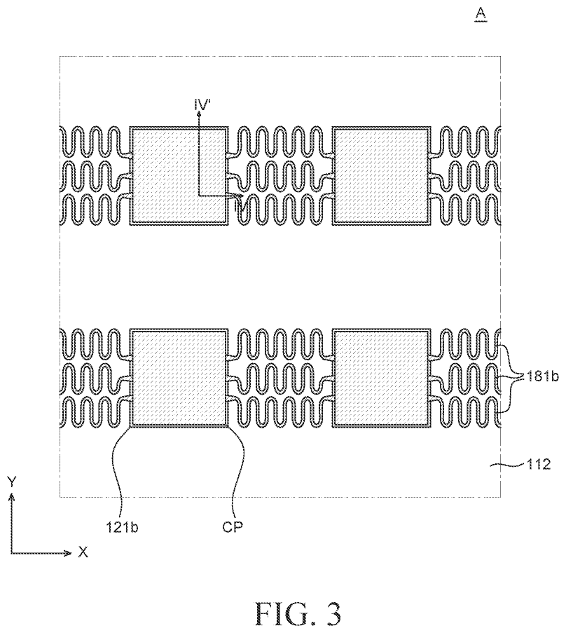

FIG. 3 is an enlarged plan view of an upper substrate 112 of a display device according to an exemplary embodiment of the present disclosure.

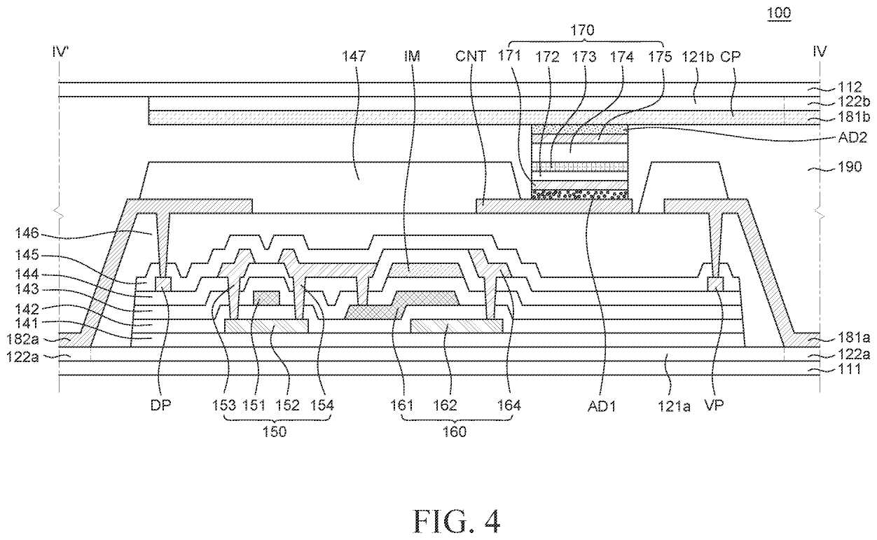

FIG. 4 is a cross-sectional view taken along the line IV-IV′ of FIGS. 2 and 3.

For the convenience of description, FIG. 1 illustrates components other than the upper substrate 112. Further, in FIG. 2, a lower substrate 111 and components disposed on the lower substrate 111 in an area A illustrated in FIG. 1 are illustrated. Further, in FIG. 3, an upper substrate 112 and components disposed on the upper substrate 112 in an area A illustrated in FIG. 1 are illustrated.

Referring to FIG. 1, a display device 100 according to an exemplary embodiment of the present disclosure includes a lower substrate 111, a pattern layer 120, a plurality of pixels PX, a gate driver GD, a data driver DD, and a power supply PS. In the exemplary embodiment, further referring to FIGS. 3 and 4, the display device 100 can further include a filling layer 190 and an upper substrate 112.

The lower substrate 111 is a substrate which supports and protects several components of the display device 100. The upper substrate 112 is a substrate which covers and protects several components of the display device 100. For example, the lower substrate 111 is a substrate which supports the pattern layer 120 on which the pixels PX, the gate driver GD, and the power supply PS are formed. The upper substrate 112 is a substrate which covers the pixels PX, the gate driver GD, and the power supply PS.

The lower substrate 111 and the upper substrate 112 which are flexible substrates can be configured by an insulating material which is bendable or extendable. For example, the lower substrate 111 and the upper substrate 112 can be formed of a silicon rubber such as polydimethylsiloxane (PDMS) or an elastomer such as polyurethane (PU) or polytetrafluoroethylene (PTFE). Accordingly, the lower substrate 111 and the upper substrate 112 can have flexibility. Depending on the exemplary embodiment, the materials of the lower substrate 111 and the upper substrate 112 can be the same, but are not limited thereto and can vary.

The lower substrate 111 and the upper substrate 112 are flexible substrates so as to be reversibly expandable and contractible. Accordingly, the lower substrate 111 can be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, or a first flexible substrate. The upper substrate 112 can be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, or a second flexible substrate. Further, moduli of elasticity of the lower substrate 111 and the upper substrate 112 can be several MPa to several hundreds of MPa. Further, a ductile breaking rate of the lower substrate 111 and the upper substrate 112 can be 100% or higher. Here, the ductile breaking rate refers to a stretching rate at a timing when an object to be stretched is broken or cracked. Further, the thickness of the lower substrate 111 can be 10 um to 1 mm, but is not limited thereto.

The lower substrate 111 can include an active area AA and a non-active area NA which encloses the active area AA in part or entirely. However, the active area AA and the non-active area NA are not mentioned to be limited to the lower substrate 111, but mentioned for the entire display device 100.

The active area AA is an area in which images are displayed in the display device 100. The plurality of pixels PX can be disposed on the active area AA. Each pixel PX can include a display element and various driving elements for driving the display element. Various driving elements can refer to at least one thin film transistor (TFT) and a capacitor, but are not limited thereto. The plurality of pixels PX can be connected to various wiring lines, respectively. For example, each of the plurality of pixels PX can be connected to various wiring lines, such as a gate line, a data line, a high potential voltage line, a low potential voltage line, a reference voltage line, and an initialization voltage line.

The non-active area NA is an area where no image is displayed. The non-active area NA is disposed to be adjacent to the active area AA. For example, the non-active area NA is an area which encloses the active area AA. However, it is not limited thereto so that the non-active area NA corresponds to an area excluding the active area AA from the lower substrate 111 and can be modified and separated in various forms. Components for driving the plurality of pixels PX disposed in the active area AA can be disposed on the non-active area NA. For example, the gate driver GD and the power supply PS can be disposed on the non-active area NA. Further, on the non-active area NA, a plurality of pads connected to the gate driver GD and the data driver DD can be disposed and each pad can be connected to each of the plurality of pixels PX of the active area AA.

The pattern layer 120 can be disposed between the lower substrate 111 and the upper substrate 112. Specifically, as illustrated in FIG. 4, the pattern layer 120 includes lower pattern layers 121a and 122a and upper pattern layers 121b and 122b. The lower pattern layers 121a and 122a are pattern layers which are disposed on the lower substrate 111 to be in contact with the lower substrate 111. The upper pattern layers 121b and 122b are pattern layers which are disposed on the upper substrate 112 to be in contact with the upper substrate 112.

Referring to FIG. 1, the pattern layer 120 includes a plurality of plate patterns 121a and 121b which is disposed as islands which are spaced apart from each other and a plurality of line patterns 122a and 122b which connects the plurality of plate patterns 121a and 121b.

Specifically, as illustrated in FIG. 2, the lower pattern layers 121a and 122a include a plurality of lower plate patterns 121a which is disposed as islands which are spaced apart from each other and a plurality of lower line patterns 122a which connects the plurality of lower plate patterns 121a. As illustrated in FIG. 3, the upper pattern layers 121b and 122b include a plurality of upper plate patterns 121b which is disposed as islands which are spaced apart from each other and a plurality of upper line patterns 122b which connects the plurality of upper plate patterns 121b.

Referring to FIGS. 1, 2, and 4, the plurality of pixels PX can be formed on the plurality of lower plate patterns 121a disposed in the active area AA. Further, the gate driver GD and the power supply PS can be disposed on the plurality of lower plate patterns 121a disposed in the non-active area NA.

In other words, the plurality of pixels PX is formed below the plurality of upper plate patterns 121b disposed in the active area AA. Further, the gate driver GD and the power supply PS are formed below the upper pattern layers 121b and 122b disposed in the non-active area NA.

The plurality of upper plate patterns 121b and the plurality of lower plate patterns 121a are individually formed. Accordingly, the plurality of upper plate patterns 121b is also referred to as a plurality of upper island patterns or upper individual patterns. The plurality of lower plate patterns 121a is also referred to as a plurality of lower island patterns or lower individual patterns.

In one exemplary embodiment, the gate driver GD can be mounted on the plurality of lower plate patterns 121a disposed in the non-active area NA. Various circuit configurations which configure the gate driver GD, such as various transistors, capacitors, and wiring lines, can be disposed on the plurality of lower plate patterns 121a disposed in the non-active area NA. However, this is illustrative, so that the exemplary embodiment of the present disclosure is not limited thereto and the gate driver GD can be mounted on the plurality of lower plate patterns 123 disposed in the non-active area NA in a chip on film (COF) manner. Alternatively, the gate driver GD may also be disposed on the plurality of lower plate patterns 123 disposed in the non-active area NA in by a chip on panel (COP), a tape automated bonding (TAB), a tape carrier package (TCP) or a gate in panel (GIP) manner, but is not limited thereto.

In one exemplary embodiment, the power supply PS can be mounted on the plurality of lower plate patterns 121a disposed in the non-active area NA. Power blocks which are disposed on different layers are disposed on the plurality of lower plate patterns 121a disposed in the non-active area NA. A lower power block and an upper power block are sequentially disposed on the plurality of lower plate patterns 121a disposed in the non-active area NA. For example, a low potential voltage can be applied to the lower power block and a high potential voltage can be applied to the upper power block. Accordingly, a low potential voltage is supplied to the plurality of pixels PX through a lower power block and a high potential voltage is supplied to the plurality of pixels PX through an upper power block.

According to the exemplary embodiment, as illustrated in FIG. 1, sizes of the plurality of lower plate patterns 121a disposed in the non-active area NA can be larger than sizes of the plurality of lower plate patterns 121a disposed in the active area AA. To be more specific, an area occupied by various circuit configurations which configure one stage of the gate driver GD is relatively larger than an area occupied by the pixels PX. Therefore, a size of the plurality of lower plate patterns 121a disposed in the non-active area NA can be larger than a size of the plurality of lower plate patterns 121a disposed in the active area AA.

Even though in FIG. 1, it is illustrated that the plurality of lower plate patterns 121a disposed in the plurality of non-active areas NA is disposed on both sides of a second direction Y in the non-active area NA, this is illustrative, but the exemplary embodiment of the present disclosure is not limited thereto. For example, the plurality of lower plate patterns 121a disposed in the non-active area can be disposed in an arbitrary area of the non-active area NA. Further, even though in FIGS. 1 and 2, the plurality of lower plate patterns 121a has a quadrangular shape, this is illustrative and the exemplary embodiment of the present disclosure is not limited thereto and the plurality of lower plate patterns 121a can be modified in various forms.

In the meantime, the plurality of lower line patterns 122a is patterns which connect adjacent lower plate patterns 121a and are referred to as lower connection patterns. For example, the plurality of lower line patterns 122a can be disposed between the plurality of lower plate patterns 121a.

The plurality of upper line patterns 122b is patterns which connect adjacent upper plate patterns 121b and are referred to as upper connection patterns. For example, the plurality of upper line patterns 122b is disposed between the plurality of upper plate patterns 121b.

In one exemplary embodiment, referring to FIG. 1, the plurality of upper line patterns 122b and the plurality of lower line patterns 122a can have a wavy shape. For example, the plurality of upper line patterns 122b and the plurality of lower line patterns 122a have a sinusoidal shape. However, this is just illustrative and the shapes of the plurality of upper line patterns 122b and the plurality of lower line patterns 122a are not limited thereto. For example, the plurality of upper line patterns 122b and the plurality of lower line patterns 122a have a zigzag shape. As another example, the plurality of upper line patterns 122b and the plurality of lower line patterns 122a can have various shapes such as a plurality of rhombic substrates which is connected at their vertexes to be extended. As described above, a number and a shape of the plurality of upper line patterns 122b and the plurality of lower line patterns 122a illustrated in FIG. 1 are illustrative and the number and the shape of the plurality of upper line patterns 122b and the plurality of lower line patterns 122a can vary depending on the design.

In one exemplary embodiment, the plurality of upper plate patterns 121b, the plurality of lower plate patterns 121a, the plurality of upper line patterns 122b, and the plurality of lower line patterns 122a are rigid patterns. For example, the plurality of upper plate patterns 121b, the plurality of lower plate patterns 121a, the plurality of upper line patterns 122b, and the plurality of lower line patterns 122a are more rigid than the lower substrate 111 and the upper substrate 112. Accordingly, moduli of elasticity of the plurality of upper plate patterns 121b, the plurality of lower plate patterns 121a, the plurality of upper line patterns 122b, and the plurality of lower line patterns 122a are higher than a modulus of elasticity of the lower substrate 111 and the upper substrate 112. The modulus of elasticity is a parameter representing a rate of deformation against the stress applied to the substrate and the higher the modulus of elasticity, the higher the hardness. Moduli of elasticity of the plurality of upper plate patterns 121b, the plurality of lower plate patterns 121a, the plurality of upper line patterns 122b, and the plurality of lower line patterns 122a can be 1000 times higher than the moduli of elasticity of the lower substrate 111 and the upper substrate 112. However, this is illustrative and the exemplary embodiment of the present disclosure is not limited thereto.

In one exemplary embodiment, each of the plurality of upper plate patterns 121b, the plurality of lower plate patterns 121a, the plurality of upper line patterns 122b, and the plurality of lower line patterns 122a can be include a plastic material having a lower flexibility than the lower substrate 111 and the upper substrate 112. For example, the plurality of upper plate patterns 121b, the plurality of lower plate patterns 121a, the plurality of upper line patterns 122b, and the plurality of lower line patterns 122a include at least one material of polyimide (PI), polyacrylate, and polyacetate. According to an exemplary embodiment, the plurality of upper plate patterns 121b, the plurality of lower plate patterns 121a, the plurality of upper line patterns 122b, and the plurality of lower line patterns 122a can be formed of the same material, but is not limited thereto and can be formed of different materials. When the plurality of upper plate patterns 121b, the plurality of lower plate patterns 121a, the plurality of upper line patterns 122b, and the plurality of lower line patterns 122a are formed of the same material, the plurality of upper plate patterns 121b and the plurality of upper line patterns 122b are integrally formed. Further, the plurality of lower plate patterns 121a and the plurality of lower line patterns 122a can be integrally formed.

In some exemplary embodiments, the lower substrate 111 can be defined to include a plurality of first lower patterns and a second lower pattern. The plurality of first lower patterns can be an area overlapping the plurality of upper plate patterns 121b and the plurality of lower plate patterns 121a of the lower substrate 111, but the second lower pattern can be an area which does not overlap the plurality of upper plate patterns 121b and the plurality of lower plate patterns 121a.

Further, the upper substrate 112 is defined to include a plurality of first upper patterns and a second upper pattern. The plurality of first upper patterns can be an area overlapping the plurality of upper plate patterns 121b and the plurality of lower plate patterns 121a of the lower substrate 112, but the second upper pattern can be an area which does not overlap the plurality of upper plate patterns 121b and lower plate patterns 121a.

At this time, moduli of elasticity of the plurality of first lower patterns and the first upper pattern can be higher than moduli of elasticity of the second lower pattern and the second upper pattern. For example, the plurality of first lower patterns and first upper patterns can be formed of the same material as the plurality of upper plate patterns 121b and lower plate patterns 121a. The second lower pattern and the second upper pattern can be formed of a material having a modulus of elasticity lower than those of the plurality of upper plate patterns 121b and lower plate patterns 121a.

For example, the first lower pattern and the first upper pattern can be formed of polyimide (PI), polyacrylate, or polyacetate. Further, the second lower pattern and the second upper pattern can be formed of silicon rubber such as polydimethylsiloxane (PDMS) or elastomer such as polyurethane (PU) or polytetrafluoroethylene.

### Driving Element of Non-Active Area

The gate driver GD supplies a gate voltage to the plurality of pixels PX disposed in the active area AA. The gate driver GD includes a plurality of stages formed on the plurality of lower plate patterns 121a disposed in the non-active area NA and each stage included in the gate driver GD can be electrically connected to each other by means of the plurality of gate connection lines. Accordingly, a gate voltage output from any one of stages can be transmitted to the other stage. Each stage can sequentially supply the gate voltage to the plurality of pixels PX connected to each stage.

The power supply PS is connected to the gate driver GD to supply a gate driving voltage and a gate clock voltage to the gate driver GD. The power supply PS is connected to the plurality of pixels PX to supply a pixel driving voltage to each of the plurality of pixels PX. Further, the power supply PS can be formed on the plurality of lower plate patterns 121a disposed in the non-active area NA. For example, the power supply PS can be formed on the plurality of lower plate patterns 121a disposed in the non-active area NA to be adjacent to the gate driver GD. A plurality of power supplies PS formed on the plurality of lower plate patterns 121a disposed in the non-active area NA is electrically connected to the gate driver GD and the plurality of pixels PX. For example, the plurality of power supplies PS formed on the plurality of lower plate patterns 121a disposed in the non-active area NA can be connected to the gate driver GD and the plurality of pixels PX by a gate power supply connection line and a pixel power supply connection line. Therefore, each of the plurality of power supplies PS supplies a gate driving voltage, a gate clock voltage, and a pixel driving voltage.

The printed circuit board PCB transmits signals and voltages for driving the display element from the control unit to the display element. Therefore, the printed circuit board PCB can also be referred to as a driving substrate. A control unit, such as an IC chip or a circuit unit, can be mounted on the printed circuit board PCB. Further, on the printed circuit board PCB, a memory or a processor can also be mounted. The printed circuit board PCB provided in the display device 100 can include a stretching area and a non-stretching area to ensure stretchability. In the non-stretching area, an IC chip, a circuit unit, a memory, and a processor are mounted and in the stretching area, wiring lines which are electrically connected to the IC chip, the circuit unit, the memory, and the processor can be disposed.

The data driver DD supplies a data voltage to the plurality of pixels PX disposed in the active area AA. The data driver DD is configured as an IC chip so that it is also referred to as a data integrated circuit D-IC. The data driver DD can be mounted in the non-stretching area of the printed circuit board PCB. For example, the data driver DD can be mounted on the printed circuit board PCB in the form of a chip on board (COB). Even though in FIG. 1, it is illustrated that the data driver DD is mounted in a chip on film (COF) manner, it is not limited thereto and the data driver DD can be mounted by a chip on board (COB), a chip on glass (COG), or a tape carrier package (TCP) manner.

Further, even though in FIG. 1, one data driver DD is disposed so as to correspond to one line of the lower plate patterns 121a disposed in the active area AA, it is not limited thereto. For example, one data driver DD can be disposed so as to correspond to a plurality of lines of lower plate patterns 121a.

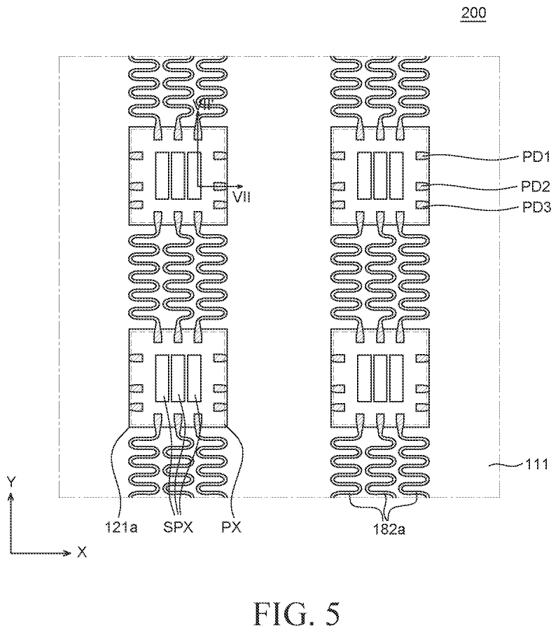

Hereinafter, the active area AA of the display device 100 according to the exemplary embodiment of the present disclosure will be described in more detail with reference to FIGS. 4 and 5 together.

### Planar and Cross-Sectional Structures of Active Area

Referring to FIGS. 2 and 4, a pixel PX including the plurality of sub pixels SPX is disposed in the lower plate pattern 121a disposed on the lower substrate 111. Each of the plurality of sub pixels SPX can include a light emitting diode 170 which is a display element and a driving transistor 160 and a switching transistor 150 which drive the light emitting diode 170. However, in the sub pixel SPX, the display element is not limited to an inorganic light emitting diode LED, and can also be changed to an organic light emitting diode OLED. For example, the plurality of sub pixels SPX can include a red sub pixel, a green sub pixel, and a blue sub pixel, but is not limited thereto and colors of the plurality of sub pixels SPX can be modified to various colors as needed.

The plurality of sub pixels SPX can be connected to the plurality of lower connection lines 181a and 182a. For example, the plurality of sub pixels SPX is electrically connected to the first lower connection line 181a extending in the first direction X and the plurality of sub pixels SPX is electrically connected to the second lower connection line 182a extending in the second direction Y.

Referring to FIGS. 2 and 4, a conductive pattern CP is disposed in the upper plate pattern 121b disposed on the upper substrate 112. The plurality of conductive patterns CP can be connected to the plurality of upper connection lines 181b. The upper connection line 181b extends in the first direction X to be electrically connected to the plurality of conductive patterns CP.

Hereinafter, a cross-sectional structure of the active area AA will be described in more detail with reference to FIG. 4.

Referring to FIG. 4, a plurality of inorganic insulating layers is disposed on the plurality of lower plate patterns 121a. For example, a plurality of inorganic insulating layers can include a buffer layer 141, a gate insulating layer 142, a first interlayer insulating layer 143, a second interlayer insulating layer 144, and a passivation layer 145. However, the exemplary embodiment of the present disclosure is not limited thereto and various inorganic insulating layers are additionally disposed on the plurality of lower plate patterns 121a. At least one of the buffer layer 141, the gate insulating layer 142, the first interlayer insulating layer 143, the second interlayer insulating layer 144, and the passivation layer 145 which are inorganic insulating layers can be omitted.

To be more specific, the buffer layer 141 is disposed on the plurality of lower plate patterns 121a. The buffer layer 141 is formed on the plurality of lower plate patterns 121a to protect various components of the display device 100 from permeation of moisture (H₂O) and oxygen (O₂) from the outside of the lower substrate 111 and the plurality of lower plate patterns 121a. The buffer layer 141 can be configured by an insulating material. For example, the buffer layer 141 can be configured by a single layer or a double layer formed of at least one of silicon nitride (SiNx), silicon oxide (SiOx), and silicon oxynitride (SiON).

The buffer layer 141 may be formed by inorganic film in a single layer or in multiple layers, for example, the inorganic film in a single layer may be a silicon oxide (SiOx) film, a silicon nitride (SiNx) film or a silicon oxynitride (SiON) film, and inorganic films in multiple layers may formed by alternately stacking two or more among one or more silicon oxide (SiOx) films, one or more silicon nitride (SiNx) films, and one or more silicon oxynitride (SiON) films, and one or more amorphous silicon (a-Si), but the present disclosure is not limited thereto.

However, the buffer layer 141 can be omitted depending on a structure or a characteristic of the display device 100.

Here, the buffer layer 141 can be formed only in an area where the lower substrate 111 overlaps the plurality of lower plate patterns 121a. As described above, the buffer layer 141 can be formed of an inorganic material so that the buffer layer 141 can be easily cracked or damaged during a process of stretching the display device 100. Therefore, the buffer layer 141 is not formed in an area between the plurality of lower plate patterns 121a, but is patterned to have a shape of the plurality of lower plate patterns 121a to be formed only above the plurality of lower plate patterns 121a. Therefore, in the display device 100 according to the exemplary embodiment of the present disclosure, the buffer layer 141 is formed only in an area overlapping the plurality of lower plate patterns 121a which are rigid patterns, but not formed in an area between the plurality of lower plate patterns 121a. Therefore, even though the display device 100 is bent or extended to be deformed, the damage of various components of the display device 100 can be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 are formed on the buffer layer 141.

First, the active layer 152 of the switching transistor 150 and the active layer 162 of the driving transistor 160 are disposed on the buffer layer 141. For example, the active layer 152 of the switching transistor 150 and the active layer 162 of the driving transistor 160 can be formed of oxide semiconductors. Alternatively, the active layer 152 of the switching transistor 150 and the active layer 162 of the driving transistor 160 can be formed of amorphous silicon (a-Si) material, polycrystalline silicon (poly-Si) material, or an organic semiconductor material , but the present disclosure is not limited thereto.

The gate insulating layer 142 is disposed on the active layer 152 of the switching transistor 150 and the active layer 162 of the driving transistor 160. The gate insulating layer 142 electrically insulates the gate electrode 151 of the switching transistor 150 from the active layer 152 of the switching transistor 150 and electrically insulates the gate electrode 161 of the driving transistor 160 from the active layer 162 of the driving transistor 160. The gate insulating layer 142 can include an insulating material. For example, the gate insulating layer 142 can be configured by a single layer of silicon nitride (SiNx) or silicon oxide (SiOx) which is an inorganic material or a multiple layer of silicon nitride (SiNx) or silicon oxide (SiOx), but it is not limited thereto.

The gate electrode 151 of the switching transistor 150 and the gate electrode 161 of the driving transistor 160 are disposed on the gate insulating layer 142. The gate electrode 151 of the switching transistor 150 and the gate electrode 161 of the driving transistor 160 are disposed on the gate insulating layer 142 to be spaced apart from each other. The gate electrode 151 of the switching transistor 150 overlaps the active layer 152 of the switching transistor 150 and the gate electrode 161 of the driving transistor 160 overlaps the active layer 162 of the driving transistor 160.

The gate electrode 151 of the switching transistor 150 and the gate electrode 161 of the driving transistor 160 can be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The first interlayer insulting layer 143 is disposed on the gate electrode 151 of the switching transistor 150 and the gate electrode 161 of the driving transistor 160. The first interlayer insulating layer 143 insulates the gate electrode 161 of the driving transistor 160 from an intermediate metal layer IM. The first interlayer insulating layer 143 can be formed of an inorganic material, similarly to the buffer layer 141. For example, the first interlayer insulating layer 143 can be configured by a single layer of silicon nitride (SiNx) or silicon oxide (SiOx) which is an inorganic material or a multiple layer of silicon nitride (SiNx) or silicon oxide (SiOx), but it is not limited thereto.

The intermediate metal layer IM is disposed on the first interlayer insulating layer 143. The intermediate metal layer IM overlaps the gate electrode 161 of the driving transistor 160. Therefore, a capacitor (for example, a storage capacitor) is formed in an overlapping area of the intermediate metal layer IM and the gate electrode 161 of the driving transistor 160. Specifically, the storage capacitor can be formed by the gate electrode 161 of the driving transistor 160, the first interlayer insulating layer 143, and the intermediate metal layer IM. However, the placement area of the intermediate metal layer IM is not limited thereto and the intermediate metal layer IM overlaps the other electrode to form the storage capacitor in various forms.

The intermediate metal layer IM can be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The second interlayer insulating layer 144 is disposed on the intermediate metal layer IM. The second interlayer insulating layer 144 insulates the gate electrode 151 of the switching transistor 150 from the source electrode 153 and the drain electrode 154 of the switching transistor 150. The second interlayer insulating layer 144 insulates the intermediate metal layer IM from the source electrode and the drain electrode 164 of the driving transistor 160. The second interlayer insulating layer 144 can be formed of an inorganic material, which is the same as the buffer layer 141. For example, the first interlayer insulating layer 143 can be configured by a single layer of silicon nitride (SiNx) or silicon oxide (SiOx) which is an inorganic material or a multiple layer of silicon nitride (SiNx) or silicon oxide (SiOx), but it is not limited thereto.

The source electrode 153 and the drain electrode 154 of the switching transistor 150 are disposed on the second interlayer insulating layer 144. The source electrode and the drain electrode 164 of the driving transistor 160 are disposed on the second interlayer insulating layer 144. The source electrode 153 and the drain electrode 154 of the switching transistor 150 are disposed on the same layer to be spaced apart from each other. Even though in FIG. 1, the source electrode of the driving transistor 160 is omitted, the source electrode of the driving transistor 160 is also disposed to be spaced apart from the drain electrode 164 on the same layer. In the switching transistor 150, the source electrode 153 and the drain electrode 154 can be in contact with the active layer 152 to be electrically connected to the active layer 152. In the driving transistor 160, the source electrode and the drain electrode 164 can be in contact with the active layer 162 to be electrically connected to the active layer 162. The drain electrode 154 of the switching transistor 150 is in contact with the gate electrode 161 of the driving transistor 160 through a contact hole to be electrically connected to the gate electrode 161 of the driving transistor 160.

The source electrode 153 and the drain electrodes 154 and 164 can include any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

Further, in this specification, even though it is described that the driving transistor 160 has a coplanar structure, various transistors such as a staggered structure can also be used. Further, in this specification, the transistor can be formed not only to have a top gate structure, but also to have a bottom gate structure.

A gate pad and a data pad DP can be disposed on the second interlayer insulating layer 144.

Specifically, the gate pad is a pad which transmits a gate voltage to the plurality of sub pixels SPX. The gate pad is connected to the first lower connection line 181a through a contact hole. Further, the gate voltage supplied from the first lower connection line 181a can be transmitted to the gate electrode 151 of the switching transistor 150 from the gate pad through a wiring line formed on the lower plate pattern 121a.

The data pad DP can be a pad which transmits a data voltage to the plurality of sub pixels SPX. The data pad DP is connected to the second lower connection line 182a through a contact hole. Further, the data voltage supplied from the second lower connection line 182a can be transmitted to the source electrode 153 of the switching transistor 150 from the data pad DP through a wiring line formed on the lower plate pattern 121a.

A voltage pad VP is a pad which transmits a high potential voltage to the plurality of sub pixels SPX. The voltage pad VP is connected to the first lower connection line 181a through a contact hole. Further, a high potential voltage supplied from the first lower connection line 181a can be transmitted to the driving transistor 160 from the voltage pad VP through a wiring line formed on the lower plate pattern 121a. The above-described high potential voltage is referred to as a second driving voltage and a low potential voltage to be described below can be referred to as a first driving voltage.

The gate pad, the data pad DP, and the voltage pad VP can be formed of the same material as the source electrode 153 and the drain electrodes 154 and 164, but are not limited thereto.

The passivation layer 145 can be formed on the switching transistor 150 and the driving transistor 160. For example, the passivation layer 145 covers the switching transistor 150 and the driving transistor 160 to protect the switching transistor 150 and the driving transistor 160 from the permeation of moisture and oxygen. The passivation layer 145 can be formed of an inorganic material and configured by a single layer or a double layer, but is not limited thereto.

The gate insulating layer 142, the first interlayer insulating layer 143, the second interlayer insulating layer 144, and the passivation layer 145 are patterned to be formed only in an area overlapping the plurality of lower plate patterns 121a. The gate insulating layer 142, the first interlayer insulating layer 143, the second interlayer insulting layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 can also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of lower plate patterns 121a, but are patterned to have a shape of the plurality of lower plate patterns 121a to be formed only above the plurality of lower plate patterns 121a.

The planarization layer 146 is formed on the passivation layer 145. The planarization layer 146 planarizes upper portions of the switching transistor 150 and the driving transistor 160. The planarization layer 146 can be configured by a single layer or a plurality of layers and can be formed of an organic material. Therefore, the additional planarization layer 146 can also be referred to as an organic insulating layer. For example, the planarization layer 146 can be formed of an acrylic organic material, but is not limited thereto.

Referring to FIG. 4, the planarization layer 146 can be disposed so as to cover top surfaces and side surfaces of the buffer layer 141, the gate insulating layer 142, the first interlayer insulating layer 143, the second interlayer insulating layer 144, and the passivation layer 145 on the plurality of lower plate patterns 121a. Further, the planarization layer 146 encloses the buffer layer 141, the gate insulating layer 142, the first interlayer insulating layer 143, the second interlayer insulating layer 144, and the passivation layer 145 together with the plurality of lower plate patterns 121a. To be more specific, the planarization layer 146 can be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of lower plate patterns 121a. Accordingly, the planarization layer 146 can supplement a step on side surfaces of the buffer layer 141, the gate insulating layer 142, the first interlayer insulating layer 143, the second interlayer insulating layer 144, and the passivation layer 145. Further, the planarization layer 146 can enhance an adhesive strength with the lower connection lines 181a and 182a disposed on a side surface of the planarization layer 146.

Referring to FIG. 4, an inclination angle of the side surface of the planarization layer 146 can be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 can have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the lower connection lines 181a and 182a which are disposed to be in contact with the side surface of the planarization layer 146 are disposed with a gentle slope so that when the display device 100 is stretched, the stress generated in the lower connection lines 181a and 182a can be reduced. Further, the side surface of the planarization layer 146 has a relatively gentle slope so that the crack of the lower connection lines 181a and 182a or separation from the side surface of the planarization layer 146 can be suppressed.

Referring to FIGS. 2 to 4, the lower connection lines 181a and 182a refer to wiring lines which electrically connect the pads on the plurality of lower plate patterns 121a. The lower connection lines 181a and 182a can be disposed on the plurality of lower line patterns 122a. Further, the lower line pattern 122a is not disposed in an area between the plurality of lower plate patterns 121a in which the lower connection lines 181a and 182a are not disposed.

The lower connection lines 181a and 182a include a first lower connection line 181a and a second lower connection line 182a. The first lower connection line 181a and the second lower connection line 182a are disposed between the plurality of lower plate patterns 121a. Specifically, the first lower connection line 181a refers to a wiring line extending in a first direction X between the plurality of lower plate patterns 121a, among the lower connection lines 181a and 182a. The second lower connection line 182a refers to a wiring line extending in a second direction Y between the plurality of lower plate patterns 121a, among the lower connection lines 181a and 182a.

The lower connection lines 181a and 182a can be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a display panel of a general display device, various wiring lines such as a plurality of gate lines and a plurality of data lines extend between the plurality of sub pixels as a straight line and the plurality of sub pixels is connected to one signal line. Therefore, in the display panel of the general display device, various wiring lines, such as a gate line, a data line, a high potential voltage line, and a reference voltage line, extend from one side to the other side of the display panel of the organic light emitting display device without being disconnected on the substrate.

In contrast, in the display device 100 according to the exemplary embodiment of the present disclosure, various wiring lines, such as a gate line, a data line, a high potential voltage line, a reference voltage line, or an initialization voltage line having a straight line shape which are considered to be used for the display panel of the general display device, is disposed only on the plurality of lower plate patterns 121a. For example, in the display device 100 according to the exemplary embodiment of the present disclosure, a linear wiring line can be disposed only on the plurality of lower plate patterns 121a.

In the display device 100 according to the exemplary embodiment of the present disclosure, the pads on two adjacent lower plate patterns 121a can be connected by the lower connection lines 181a and 182a. Accordingly, the lower connection lines 181a and 182a electrically connect the gate pads, the data pads DP, or the voltage pad VP on two adjacent lower plate patterns 121a. Accordingly, the display device 100 according to the exemplary embodiment of the present disclosure can include a plurality of lower connection lines 181a and 182a which electrically connects various wiring lines, such as a gate line, a data line, a high potential voltage line, and a reference voltage line, between the plurality of lower plate patterns 121a. For example, the gate line can be disposed on the plurality of lower plate patterns 121a disposed to be adjacent to each other in the first direction X and the gate pad can be disposed on both ends of the gate line. In this case, the plurality of gate pads on the plurality of lower plate patterns 121a adjacent to each other in the first direction X can be connected to each other by the first lower connection line 181a which serves as a gate line. Therefore, the gate line disposed on the plurality of lower plate patterns 121a and the first lower connection line 181a disposed on the lower line pattern 122a can serve as one gate line. The above-described gate line can be referred to as a scan signal line. Further, wiring lines which extend in the first direction X, among all various wiring lines which can be included in the display device 100, such as an emission signal line and a high potential voltage line, can also be electrically connected by the first lower connection line 181a, as described above.

Referring to FIGS. 2 and 4, the first lower connection lines 181a can connect the voltage pads VP on two lower plate patterns 121a which are disposed side by side, among the voltage pads VP on the plurality of lower plate patterns 121a disposed to be adjacent in the first direction X. The first lower connection line 181a serves as a scan signal line and an emission signal line which are gate lines, but is not limited thereto. The voltage pads VP on the plurality of lower plate patterns 121a disposed in the first direction X can be connected by the first lower connection line 181a serving as a high potential voltage line and transmit one high potential voltage.

Further, the second lower connection line 182a can connect the data pads DP on two lower plate patterns 121a which are disposed side by side, among the data pads DP on the plurality of lower plate patterns 121a disposed to be adjacent in the second direction Y. The second lower connection line 182a can serve as a data line or a reference voltage line, but is not limited thereto. An internal line on the plurality of lower plate patterns 121a disposed in the second direction Y can be connected by the plurality of second lower connection lines 182a serving as data lines and transmit one data voltage.

As illustrated in FIG. 4, the first lower connection line 181a is disposed to be in contact with a top surface and a side surface of the planarization layer 146 disposed on the lower plate pattern 121a. The first lower connection line 181a can extend to the top surface of the lower line pattern 122a. Further, the second lower connection line 182a is disposed to be in contact with a top surface and a side surface of the planarization layer 146 disposed on the lower plate pattern 121a. The second lower connection line 182a can extend to the top surface of the lower line pattern 122a.

However, there is no need to dispose a rigid pattern in an area in which the first lower connection line 181a and the second lower connection line 182a are not disposed, so that the lower line pattern 122a which is a rigid pattern is not disposed below the first lower connection line 181a and the second lower connection line 182a.

In the meantime, referring to FIG. 4, a bank 147 is formed on the connection pad CNT, the lower connection lines 181a and 182a, and the planarization layer 146. The bank 147 is a component which divides adjacent sub pixels SPX. The bank 147 is disposed so as to cover at least a part of the connection pad CNT, the lower connection lines 181a and 182a, and the planarization layer 146. The bank 147 can be formed of an insulating material. Further, the bank 147 can include a black material. The bank 147 includes the black material to block wiring lines which can be visible through the active area AA. For example, the bank 147 can be formed of a transparent carbon based mixture and for example, include carbon black. However, it is not limited thereto and the bank 147 can be formed of a transparent insulating material. Alternatively, the bank 147 may also be formed of a color pigment. Even though in FIG. 4, it is illustrated that a height of the bank 147 is lower than a height of the light emitting diode 170, the present disclosure is not limited thereto and the height of the bank 147 can be equal to the height of the light emitting diode 170.

Referring to FIG. 4, the light emitting diode 170 is disposed on the connection pad CNT and the first lower connection line 181a. The light emitting diode 170 includes a first electrode 171, a first semiconductor layer 172, an emission layer 173, a second semiconductor layer 174, and a second electrode 175. The first semiconductor layer 172, the emission layer 173, the second semiconductor layer 174, and the second electrode 175 are sequentially disposed on the first electrode 171. Therefore, the light emitting diode 170 is a vertical light emitting diode 170 in which the second electrode 175 is disposed on the first electrode 171.

The first semiconductor layer 172 is disposed on the first adhesive layer AD1 and the second semiconductor layer 174 is disposed on the first semiconductor layer 172. The first semiconductor layer 172 and the second semiconductor layer 174 can be layers formed by doping n-type and p-type impurities into a specific material. For example, the first semiconductor layer 172 and the second semiconductor layer 174 can be layers formed by doping p type and n type impurities into a material, such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium, and tin (Sn), but are not limited thereto.

The emission layer 173 is disposed between the first semiconductor layer 172 and the second semiconductor layer 174. The emission layer 173 is supplied with holes and electrons from the first semiconductor layer 172 and the second semiconductor layer 174 to emit light. The emission layer 173 can be formed by a single layer or a multi-quantum well (MQW) structure, and for example, can be formed of indium gallium nitride (InGaN) or gallium nitride (GaN), but is not limited thereto.

The first electrode 171 is disposed below the first semiconductor layer 172. The first electrode 171 is disposed on the bottom surface of the first semiconductor layer 172. The first electrode 171 is an electrode which electrically connects the driving transistor 160 and the first semiconductor layer 172. The first electrode 171 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 175 is disposed on the second semiconductor layer 174. The second electrode 175 is disposed on the top surface of the second semiconductor layer 174. The second electrode 175 is an electrode which electrically connects the conductive pattern CP and the second semiconductor layer 174. The second electrode 175 can be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first adhesive layer AD1 is disposed between the connection pad CNT and the first electrode 171 so that the light emitting diode 170 is bonded onto the connection pad CNT. The second adhesive layer AD2 is disposed between the conductive pattern CP and the second electrode 175 so that the light emitting diode 170 is bonded below the conductive pattern CP.

The first adhesive layer AD1 and the second adhesive layer AD2 can be conductive adhesive layers in which conductive balls are dispersed in an insulating base member. Therefore, when heat or a pressure is applied to the adhesive layer AD, the conductive balls are electrically connected in a portion applied with the heat or pressure to have a conductive property.

The connection pad CNT is electrically connected to the drain electrode 164 of the driving transistor 160 to be applied with a driving voltage from the driving transistor 160 to drive the light emitting diode 170. Even though in FIG. 4, it is illustrated that the connection pad CNT is not in direct contact with the drain electrode 164 of the driving transistor 160, but is in indirect contact therewith, the present disclosure is not limited thereto. Therefore, the connection pad CNT and the drain electrode 164 of the driving transistor 160 can be in direct contact with each other. Further, a low potential voltage is applied to the first lower connection line 181a to drive the light emitting diode 170.

In the meantime, referring to FIG. 4, with respect to the upper substrate 112, the plurality of upper plate patterns 121b and the plurality of upper line patterns 122b which connects the plurality of upper plate patterns 121b can be disposed on the upper substrate 112. Referring to FIG. 4, with respect to the lower substrate 111, the plurality of upper plate patterns 121b and the plurality of upper line patterns 122b which connects the plurality of upper plate patterns 121b can be disposed below the upper substrate 112. For example, the plurality of upper plate patterns 121b and the plurality of upper line patterns 122b are disposed to be in contact with the upper substrate 112.

Specifically, the plurality of upper line patterns 122b connects upper plate patterns 121b which are disposed to be adjacent to each other in the first direction X. Therefore, the plurality of upper line patterns 122b extends in the first direction X. However, it is not limited thereto and the plurality of upper line patterns 122b can extend to the first direction X or to the first direction X and the second direction Y.

With respect to the upper substrate 112, the conductive pattern CP is disposed on the upper plate pattern 121b and the upper connection line 181b is disposed on the upper line pattern 122b. With respect to the lower substrate 111, the conductive pattern CP is disposed below the upper plate pattern 121b and the upper connection line 181b is disposed below the upper line pattern 122b.

The conductive pattern CP can have the same shape as the upper plate pattern 121b. For example, the upper plate pattern 121b has island shapes which are spaced apart from each other so that the conductive patterns CP also have island shapes which are spaced apart from each other. However, the shape of the conductive pattern CP is not limited thereto and can vary with various shapes overlapping the shape of the upper plate pattern 121b.

The upper connection line 181b also has the same shape as the upper line pattern 122b. For example, the upper connection line 181b can also have a sinusoidal shape. However, it is just illustrative, so that the shape of the plurality of upper connection lines 181b is not limited thereto. For example, the plurality of upper line patterns 122b and the plurality of upper connection lines 181b have a zigzag shape. As another example, the plurality of upper connection lines 181b can have various shapes, such as a plurality of rhombic substrates being connected and extending at vertices.

The plurality of conductive patterns CP and the plurality of upper connection lines 181b can be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti). However, it is not limited thereto. The plurality of conductive patterns CP and the plurality of upper connection lines 181b can be integrally formed, but it is not limited thereto.

A low potential voltage for driving the light emitting diode 170 can be applied to the plurality of conductive patterns CP and the plurality of upper connection lines 181b. For example, the plurality of conductive patterns CP and the plurality of upper connection lines 181b can configure a conductive surface to which one low potential voltage is applied.

Therefore, when the display device 100 is on, the driving voltage is applied to the first electrode 171 by means of the connection pad CNT and the low potential voltage is applied to the second electrode by means of the conductive pattern CP. Therefore, different voltage levels are transmitted to the first electrode 171 and the second electrode 175 to allow the light emitting diode 170 to emit light.

The filling layer 190 is disposed on the entire surface of the lower substrate 111 to be filled between the components disposed on the upper substrate 112 and the lower substrate 111. The filling layer 190 can be configured by a curable adhesive. Specifically, the material which configures the filling layer 190 is coated on the entire surface of the lower substrate 111 and then is cured so that the filling layer 190 can be disposed between the upper substrate 112 and the components disposed on the lower substrate 111. For example, the filling layer 190 can be an optically clear adhesive (OCA) and can be configured by an acrylic adhesive, a silicon based adhesive, and a urethane based adhesive.

As described above, the display device according to the exemplary embodiment of the present disclosure supplies a low potential voltage to the light emitting diode by means of the upper connection line 181b and the conductive pattern CP attached to the upper substrate 112.

A total area of the upper connection line 181b and the conductive pattern CP is larger than a total area of the lower connection lines 181a and 182a so that a total resistance of the upper connection line 181b and the conductive pattern CP can be relatively low.

Therefore, the voltage drop of the low potential voltage which is supplied through the upper connection line 181b and the conductive pattern CP can be suppressed. Accordingly, a stable low potential voltage can be supplied to the light emitting diode 170.

As a result, the display device according to the exemplary embodiment of the present disclosure ensures a luminous efficiency and a stability of the light emitting diode 170 to improve an image quality.

### Another Embodiment of Present Disclosure

Hereinafter, a display device according to another exemplary embodiment of the present disclosure will be described. The difference between the display device according to the exemplary embodiment of the present disclosure and a display device according to another exemplary embodiment of the present disclosure is a conductive pattern and a connection relationship thereof, which will be mainly described. In the display device according to the exemplary embodiment of the present disclosure and the display device according to another exemplary embodiment of the present disclosure, like component is denoted by like reference numeral and a redundant description will be omitted or may be briefly discussed. The display device of FIGS. 5-7 can have some same or similar components of the display device of other embodiments while having configurations discussed in more detail below.

More specifically, FIG. 5 is an enlarged plan view of a lower substrate of a display device according to an exemplary embodiment of the present disclosure.

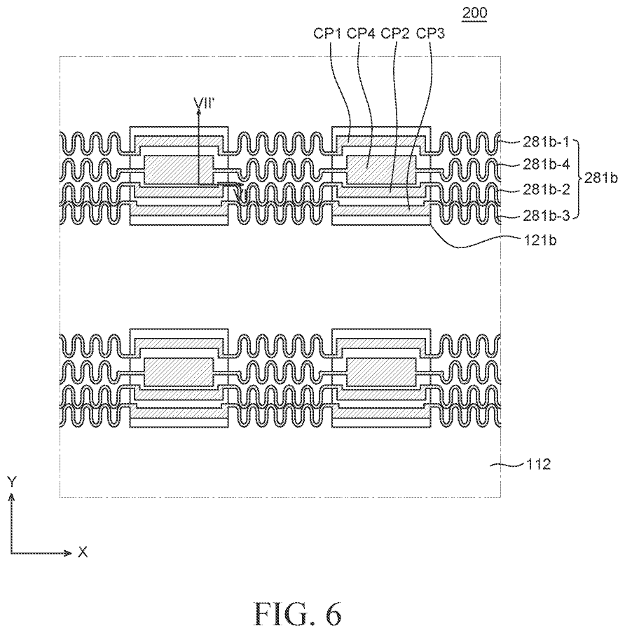

FIG. 6 is an enlarged plan view of an upper substrate of a display device according to another exemplary embodiment of the present disclosure.

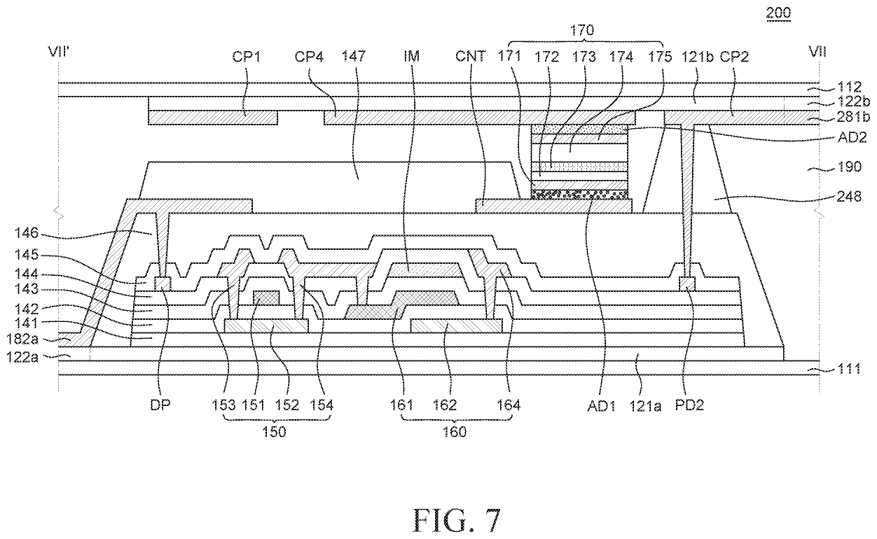

FIG. 7 is a cross-sectional view taken along the line VII-VII′ of FIGS. 5 and 6.

Referring to FIG. 5, a plurality of pads PD1, PD2, and PD3 is disposed on the lower plate pattern 121a. To be more specific, at least one pair of pads PD1, PD2, and PD3 can be disposed on both sides of the lower plate pattern 121a in the first direction X. At least one pair of pads PD1, PD2, and PD3 can be electrically connected through a wiring line and an element formed on the lower plate pattern 121a.

For example, one pair of first pads PD1, one pair of second pad PD2, and one pair of third pads PD3 can be disposed on the lower plate pattern 121a. One pair of first pads PD1 can be pads for transmitting a high potential voltage to the plurality of sub pixels SPX. One pair of second pads PD2 can be pads for transmitting an emission signal, among the gate voltages, to the plurality of sub pixels SPX. One pair of third pads PD3 can be pads for transmitting a scan signal, among the gate voltages, to the plurality of sub pixels SPX.

Referring to FIGS. 6 and 7, with respect to the upper substrate 112, a plurality of conductive patterns CP1, CP2, CP3, and CP4 is disposed on the upper plate pattern 121b and a plurality of upper connection lines 281b is disposed on the plurality of upper line patterns 122b. Referring to FIG. 7, with respect to the lower substrate 111, a plurality of conductive patterns CP1, CP2, CP3, and CP4 is disposed below the upper plate pattern 121b and a plurality of upper connection lines 281b is disposed below the plurality of upper line patterns 122b.

To be more specific, a first conductive pattern CP1, a second conductive pattern CP2, a third conductive pattern CP3, and a fourth conductive pattern CP4 are disposed on one upper plate pattern 121b. The first conductive pattern CP1, the second conductive pattern CP2, the third conductive pattern CP3, and the fourth conductive pattern CP4 are electrically isolated to be applied with different voltages or signals.

For example, a high potential voltage is applied to the first conductive pattern CP1. The emission signal, among the gate voltages, is applied to the second conductive pattern CP2. The scan signal, among the gate voltages, is applied to the third conductive pattern CP3. A low potential voltage is applied to the fourth conductive pattern CP4.

Each of the first conductive pattern CP1, the second conductive pattern CP2, the third conductive pattern CP3, and the fourth conductive pattern CP4 can have a rectangular shape extending in the first direction X. However, the shapes of the first conductive pattern CP1, the second conductive pattern CP2, the third conductive pattern CP3, and the fourth conductive pattern CP4 are not limited thereto and can vary in various shapes to overlap the shape of the upper plate pattern 121b.

A width of the fourth conductive pattern CP4 to which a low potential voltage is applied can be larger than widths of the first conductive pattern CP1, the second conductive pattern CP2, and the third conductive pattern CP3. Therefore, the resistance of the fourth conductive pattern CP4 to which the low potential voltage is applied can be minimized. Accordingly, the low potential voltage drop can be minimized.

In the meantime, a first upper connection line 281b-1, a second upper connection line 281b-2, a third upper connection line 281b-3, and a fourth upper connection line 281b-4 are disposed on the plurality of upper line patterns 122b.

The first upper connection line 281b-1 is electrically connected to the first conductive pattern CP1. The second upper connection line 281b-2 is electrically connected to the second conductive pattern CP2. The third upper connection line 281b-3 is electrically connected to the third conductive pattern CP3. The fourth upper connection line 281b-4 is electrically connected to the fourth conductive pattern CP4.

Therefore, the high potential voltage is supplied through the first upper connection line 281b-1 and the first conductive pattern CP1. Therefore, the emission signal, among the gate voltages, is supplied through the second upper connection line 281b-2 and the second conductive pattern CP2. The scan signal, among the gate voltages, is supplied through the third upper connection line 281b-3 and the third conductive pattern CP3. The low potential voltage is supplied through the fourth upper connection line 281b-4 and the fourth conductive pattern CP4.

Each of the first upper connection line 281b-1, the second upper connection line 281b-2, the third upper connection line 281b-3, and the fourth upper connection line 281b-4 can have the same shape as the upper line pattern 122b. For example, each of the first upper connection line 281b-1, the second upper connection line 281b-2, the third upper connection line 281b-3, and the fourth upper connection line 281b-4 can have a sinusoidal shape. However, it is just illustrative, so that the shape of the plurality of upper connection lines 281b is not limited thereto. For example, the plurality of upper line patterns 122b and the plurality of upper connection lines 281b have a zigzag shape. As another example, the plurality of upper connection lines 281b can have various shapes, such as a plurality of rhombic substrates being connected and extending at vertices.

Each of the first conductive pattern CP1, the second conductive pattern CP2, the third conductive pattern CP3, and the fourth conductive pattern CP4, and each of the first upper connection line 281b-1, the second upper connection line 281b-2, the third upper connection line 281b-3, and the fourth upper connection line 281b-4 can be configured with a metal material, such as copper (Cu), aluminum (Al), titanium (Ti), or molybdenum (Mo), or a stacked structure of a metal material, such as copper/molybdenum-titanium (Cu/Moti) or titanium/aluminum/titanium (Ti/Al/Ti), but is not limited thereto. The first conductive pattern CP1 and the first upper connection line 281b-1 can be integrally formed. The second conductive pattern CP2 and the second upper connection line 281b-2 can be integrally formed. The third conductive pattern CP3 and the third upper connection line 281b-3 can be integrally formed. The fourth conductive pattern CP4 and the fourth upper connection line 281b-4 can be integrally formed.

Referring to FIGS. 5 to 7, the first conductive pattern CP1 is electrically connected to the first pad PD1 through the first contact hole. Therefore, the high potential voltage supplied from the first conductive pattern CP1 can be transmitted to the driving transistor 160 through the first pad PD1.

The second conductive pattern CP2 is electrically connected to the second pad PD2 through a second contact hole. Therefore, the emission signal, among the gate voltages supplied from the second conductive pattern CP2, can be transmitted to the gate electrode of the emission transistor.

The third conductive pattern CP3 is electrically connected to the third pad PD3 through a third contact hole. Therefore, the scan signal, among the gate voltages supplied from the third conductive pattern CP3, can be transmitted to the gate electrode of the emission transistor.

In the meantime, a spacer 248 can be disposed between the planarization layer 146 and the first conductive pattern CP1. The spacer 248 can also be disposed between the planarization layer 146 and the second conductive pattern CP2. The spacer 248 can also be disposed between the planarization layer 146 and the third conductive pattern CP3. For example, the spacer 248 can be in contact with bottom surfaces of the first conductive pattern CP1, the second conductive pattern CP2, and the third conductive pattern CP3. The spacer 248 is formed on a top surface of the planarization layer 146. . However, the arrangement of spacer 248 is not limited thereto, for example, the spacer 248 is formed between a bottom surface of one or more of the first conductive pattern CP1, the second conductive pattern CP2, and the third conductive pattern CP3 and a top surface of the planarization layer 146.

The spacer 248 described above can serve to maintain an interval between the first conductive pattern CP1, the second conductive pattern CP2, and the third conductive pattern CP3 and the planarization layer 146.

A first contact hole which connects the first conductive pattern CP1 and the first pad PD1 can be formed to pass through the spacer 248 disposed between the planarization layer 146 and the first conductive pattern CP1. A second contact hole which connects the second conductive pattern CP2 and the second pad PD2 can be formed to pass through the spacer 248 disposed between the planarization layer 146 and the second conductive pattern CP2. A third contact hole which connects the third conductive pattern CP3 and the third pad PD3 can be formed to pass through the spacer 248 disposed between the planarization layer 146 and the third conductive pattern CP3.

A low potential voltage for driving the light emitting diode 170 can be applied to the fourth conductive pattern CP4 and the fourth upper connection line 281b-4. For example, the plurality of conductive patterns CP1, CP2, CP3, and CP4 and the plurality of upper connection lines 281b can configure a conductive surface to which one low potential voltage is applied.

Therefore, when the display device 200 is on, the driving voltage is applied to the first electrode 171 by means of the connection pad CNT and the low potential voltage is applied to the second electrode by means of the fourth conductive pattern CP4. Therefore, different voltage levels are transmitted to the first electrode 171 and the second electrode 175 to allow the light emitting diode 170 to emit light.

As described above, the display device according to another exemplary embodiment of the present disclosure applies not only a low potential voltage, but also a high potential voltage and a gate voltage, through the plurality of upper connection lines 281b disposed on the upper substrate 112.

Therefore, in the display device according to another exemplary embodiment of the present disclosure, a connection line for applying the high potential voltage and the gate voltage can be removed from the lower substrate 111.

Accordingly, a number of connection lines on the lower substrate 111 is reduced so that a resistance for stretching the display device can be improved. As a result, a stretching rate of the display device 200 according to another exemplary embodiment of the present disclosure can be improved.

### Still Another Embodiment of Present Disclosure

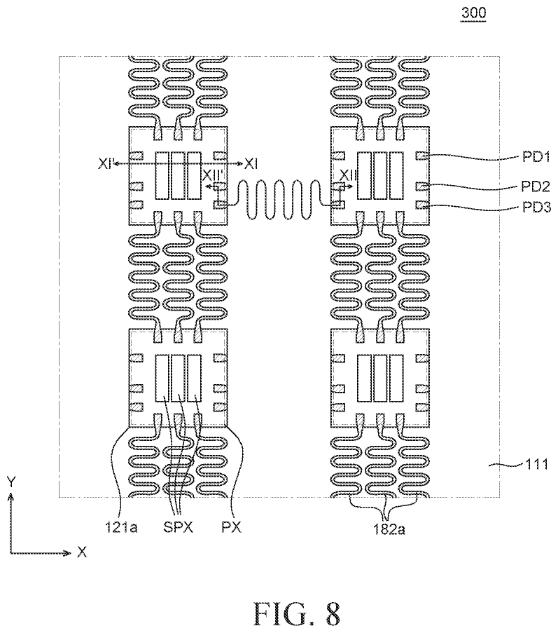

Hereinafter, a display device according to still another exemplary embodiment of the present disclosure will be described. Difference(s) between the display device according to the exemplary embodiment of the present disclosure and a display device according to another exemplary embodiment of the present disclosure include a conductive pattern and a connection relationship thereof, which will be mainly described. In the display device according to the exemplary embodiment of the present disclosure and the display device according to still another exemplary embodiment of the present disclosure, like component is denoted by like reference numeral and a redundant description will be omitted or may be briefly discussed. The display device of FIGS. 8-12 can have some same or similar components of the display device of other embodiments while having configurations discussed in more detail below.

More specifically, FIG. 8 is an enlarged plan view of a lower substrate of a display device according to still another exemplary embodiment of the present disclosure.

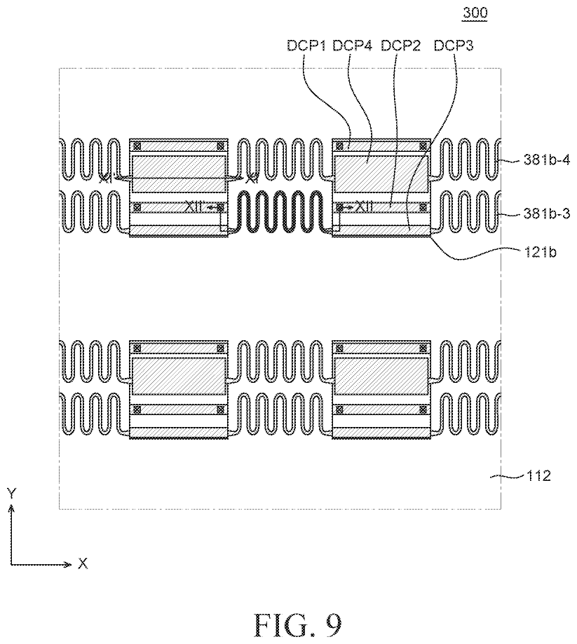

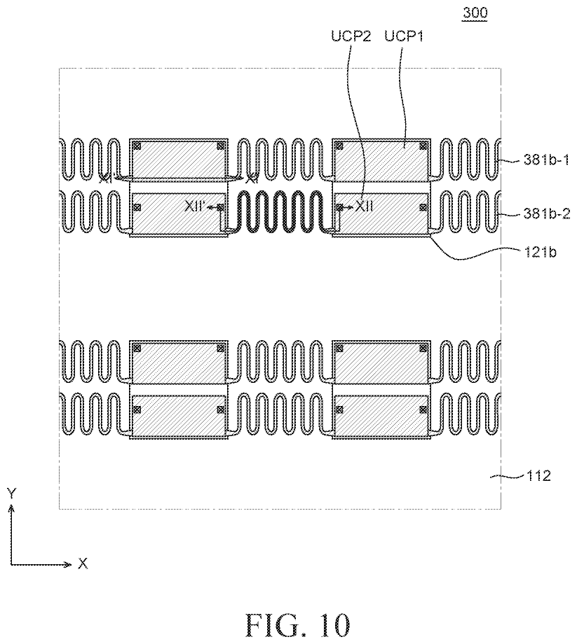

FIGS. 9 and 10 are enlarged plan views of an upper substrate of a display device according to another exemplary embodiment of the present disclosure.

Specifically, in FIG. 9, a component disposed on a first layer of the upper substrate of the display device is illustrated and in FIG. 10, a configuration disposed on a second layer on the first layer on the upper substrate of the display device is illustrated.

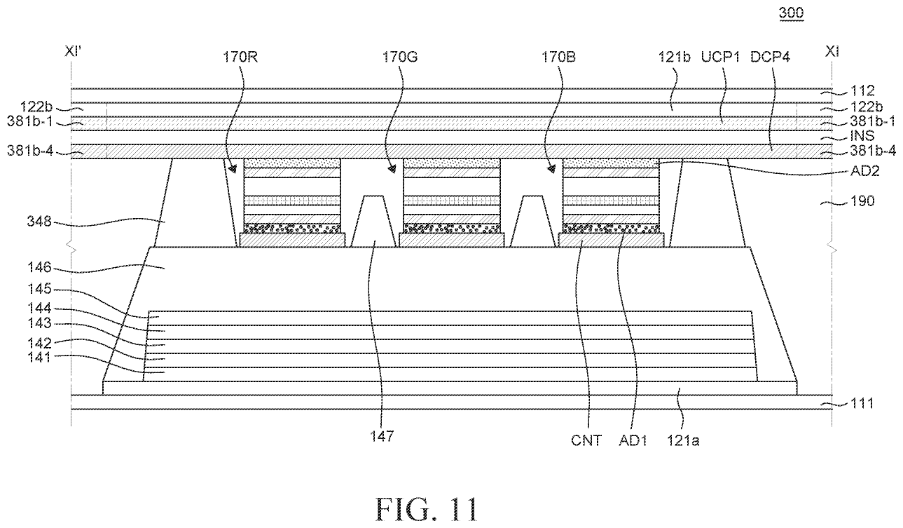

FIG. 11 is a cross-sectional view taken along the line XI-XI′ of FIGS. 8 to 10.

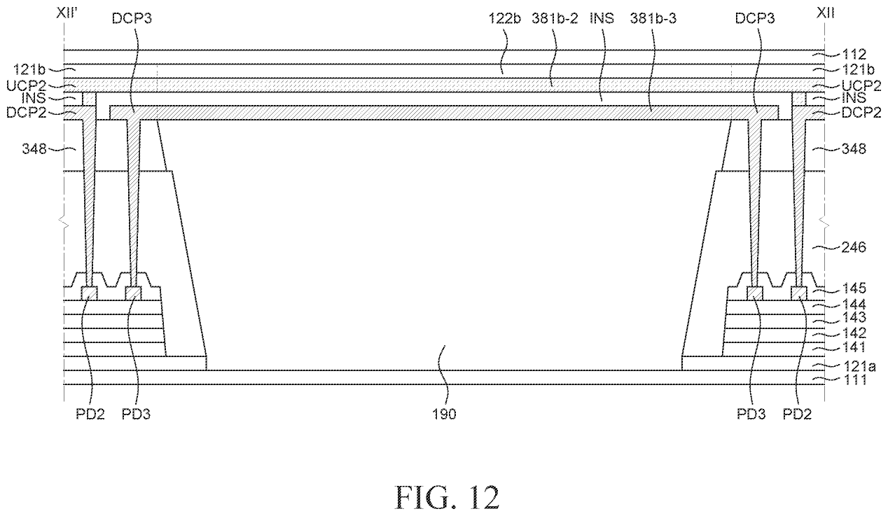

FIG. 12 is a cross-sectional view taken along the line XII-XII′ of FIGS. 8 to 10.

Referring to FIG. 8, a plurality of pads PD1, PD2, and PD3 is disposed on the lower plate pattern 121a. To be more specific, at least one pair of pads can be disposed on both sides of the lower plate pattern 121a in the first direction X. At least one pair of pads PD1, PD2, and PD3 can be electrically connected through a wiring line and an element formed on the lower plate pattern 121a.

For example, one pair of first pads PD1, one pair of second pads PD2, and one pair of third pads PD3 can be disposed on the lower plate pattern 121a. One pair of the first pads PD1 can be pads for transmitting a high potential voltage to the plurality of sub pixels SPX. One pair of the second pad PD2 can be pads for transmitting an emission signal, among the gate voltages, to the plurality of sub pixels SPX. One pair of the third pad PD3 can be pads for transmitting a scan signal, among the gate voltages, to the plurality of sub pixels SPX.

Referring to FIGS. 9 and 10, with respect to the upper substrate 112, a plurality of lower conductive patterns DCP1, DCP2, DCP3, and DCP4 and a plurality of upper conductive patterns UCP1 and CUP2 are disposed on the upper plate pattern 121b. Further, a plurality of upper connection lines 381b-1, 381b-2, 381b-3, and 381b-4 is disposed on the plurality of upper line patterns 122b. Referring to FIGS. 11 and 12, with respect to the upper substrate 111, the plurality of lower conductive patterns DCP1, DCP2, DCP3, and DCP4 and the plurality of upper conductive patterns UCP1 and CUP2 are disposed below the upper plate pattern 121b. A plurality of upper connection lines 381b-1, 381b-2, 381b-3, and 381b-4 is disposed below the plurality of upper line patterns 122b.

To be more specific, referring to FIG. 9, a first lower conductive pattern DCP1, a second lower conductive pattern DCP2, a third lower conductive pattern DCP3, and a fourth lower conductive pattern DCP4 are disposed on the first layer on one upper plate pattern 121b. The first lower conductive pattern DCP1, the second lower conductive pattern DCP2, the third lower conductive pattern DCP3, and the fourth lower conductive pattern DCP4 are electrically isolated to be applied with different voltages or signals.

For example, a high potential voltage is applied to the first lower conductive pattern DCP1. The emission signal, among the gate signals, is applied to the second lower conductive pattern DCP2. The scan signal, among the gate signals, is applied to the third lower conductive pattern DCP3. A low potential voltage is applied to the fourth lower conductive pattern DCP4.

Each of the first lower conductive pattern DCP1, the second lower conductive pattern DCP2, the third lower conductive pattern DCP3, and the fourth lower conductive pattern DCP4 can have a rectangular shape extending in the first direction X. However, the shapes of the first lower conductive pattern DCP1, the second lower conductive pattern DCP2, the third lower conductive pattern DCP3, and the fourth lower conductive pattern DCP4 are not limited thereto and can vary in various shapes to overlap the shape of the upper plate pattern 121b.

A width of the fourth lower conductive pattern DCP4 to which a low potential voltage is applied can be larger than widths of the first lower conductive pattern DCP1, the second lower conductive pattern DCP2, the third lower conductive pattern DCP3. Therefore, the resistance of the fourth lower conductive pattern DCP4 to which the low potential voltage is applied can be minimized. Accordingly, the low potential voltage drop can be minimized.

In the meantime, a third upper connection line 381b-3 and a fourth upper connection line 381b-4 are disposed on the first layer on the plurality of upper line patterns 122b.

The third upper connection line 381b-3 is electrically connected to the third lower conductive pattern DCP3. The fourth upper connection line 381b-4 is electrically connected to the fourth lower conductive pattern DCP4.

The scan signal, among the gate voltages, is supplied through the third upper connection line 381b-3 and the third lower conductive pattern DCP3. The low potential voltage is supplied through the fourth upper connection line 381b-4 and the fourth lower conductive pattern DCP4.

In the meantime, referring to FIG. 10, a first upper conductive pattern UCP1 and a second upper conductive pattern UCP2 are disposed on the plurality of lower conductive patterns DCP1, DCP2, DCP3, and DCP4. The first upper conductive pattern UCP1 and the second upper conductive pattern UCP2 are electrically isolated to be applied with different voltages or signals.

For example, a high potential voltage is applied to the first upper conductive pattern UCP1. The emission signal, among the gate signals, is applied to the second upper conductive pattern UCP2.

The first upper conductive pattern UCP1 and the second upper conductive pattern UCP2 have a rectangular shape extending in the first direction X. However, the first upper conductive pattern UCP1 and the second upper conductive pattern UCP2 are not limited thereto and can vary with various shapes overlapping the shape of the upper plate pattern 121b.

Referring to FIG. 11, an insulating layer INS is disposed between the plurality of lower conductive patterns DCP1, DCP2, DCP3, and DCP4 and the first upper conductive pattern UCP1 and the second upper conductive pattern UCP2. However, the first upper conductive pattern UCP1 is electrically connected to the first lower conductive pattern DCP1 through a contact hole. Referring to FIG. 12, the second upper conductive pattern UCP2 is electrically connected to the second lower conductive pattern DCP2 through a contact hole.

Therefore, the high potential voltage is applied to the first upper conductive pattern UCP1 and the first lower conductive pattern DCP1. An emission signal, among the gate voltages, is applied to the second upper conductive pattern UCP2 and the second lower conductive pattern DCP2.

The first upper connection line 381b-1 and the second upper connection line 381b-2 are disposed on the third upper connection line 381b-3 and the fourth upper connection line 381b-4.

To be more specific, referring to FIG. 12, the second upper connection line 381b-2 is disposed on the third upper connection line 381b-3 and the third upper connection line 381b-3 and the second upper connection line 381b-2 are insulated by the insulating layer INS.

The first upper connection line 381b-1 is disposed on the fourth upper connection line 381b-4 and the fourth upper connection line 381b-4 and the first upper connection line 381b-1 are insulated by the insulating layer INS.

In summary, the first lower conductive pattern DCP1, the second lower conductive pattern DCP2, the third lower conductive pattern DCP3, and the fourth lower conductive pattern DCP4 and the third upper connection line 381b-3 and the fourth upper connection line 381b-4 are disposed on the first layer on the upper pattern layers 121b and 122b.

The first upper conductive pattern UCP1 and the second upper conductive pattern UCP2 and the first upper connection line 381b-1 and the second upper connection line 381b-2 are disposed on the second layer on the upper pattern layers 121b and 122b.

The first upper connection line 381b-1 is electrically connected to the first upper conductive pattern UCP1. The first upper conductive pattern UCP1 and the first lower conductive pattern DCP1 are electrically connected so that the high potential voltage is applied through the first upper conductive pattern UCP1, the first lower conductive pattern DCP1, and the first upper connection line 381b-1.

The second upper connection line 381b-2 is electrically connected to the second upper conductive pattern UCP2. The second upper conductive pattern UCP2 and the second lower conductive pattern DCP2 are electrically connected so that the emission signal, among the gate voltages, is applied through the second upper conductive pattern UCP2, the second lower conductive pattern DCP2, and the second upper connection line 381b-2.

Each of the first upper connection line 381b-1, the second upper connection line 381b-2, the third upper connection line 381b-3, and the fourth upper connection line 381b-4 can have the same shape as the upper line pattern 122b. For example, each of the first upper connection line 381b-1, the second upper connection line 381b-2, the third upper connection line 381b-3, and the fourth upper connection line 381b-4 can have a sinusoidal shape. However, this is just illustrative so that the shape of the plurality of upper connection lines 381b-1, 381b-2, 381b-3, and 381b-4 is not limited thereto. For example, the plurality of upper line patterns 122b and the plurality of upper connection lines 381b-1, 381b-2, 381b-3, and 381b-4 have a zigzag shape. As another example, the plurality of upper connection lines 381b-1, 381b-2, 381b-3, and 381b-4 can have various shapes, such as a plurality of rhombic substrates being connected and extending at vertices.

The plurality of upper conductive patterns UCP1 and UCP2, the plurality of lower conductive patterns DCP1, DCP2, DCP3, and DCP4, and the plurality of upper connection lines 381b-1, 381b-2, 381b-3, and 381b-4 can be formed of a metal material such as copper (Cu), aluminum (Al), titanium (Ti), and molybdenum or a stacked structure of metal materials such as copper/molybdenum-titanium (Cu/Moti) or titanium/aluminum/titanium (Ti/Al/Ti). However, it is not limited thereto. The first upper conductive pattern UCP1 and the first upper connection line 381b-1 can be integrally formed. The second upper conductive pattern UCP2 and the second upper connection line 381b-2 can be integrally formed. The third lower conductive pattern DCP3 and the third upper connection line 381b-3 can be integrally formed. The fourth lower conductive pattern DCP4 and the fourth upper connection line 381b-4 can be integrally formed.

Referring to FIGS. 8 and 9, the first lower conductive pattern DCP1 is electrically connected to the first pad PD1 through the first contact hole. Therefore, the high potential voltage supplied from the first lower conductive pattern DCP1 can be transmitted to the driving transistor 160 through the first pad PD1.

Referring to FIG. 12, the second lower conductive pattern DCP2 is electrically connected to the second pad PD2 through a second contact hole. Therefore, the emission signal, among the gate voltages supplied from the second lower conductive pattern DCP2, can be transmitted to the gate electrode of the emission transistor.

The third lower conductive pattern DCP3 is electrically connected to the third pad PD3 through a third contact hole. Therefore, the scan signal, among the gate voltages supplied from the third lower conductive pattern DCP3, can be transmitted to the gate electrode of the emission transistor.

In the meantime, referring to FIGS. 11 and 12, a spacer 348 is disposed between the planarization layer 146 and the first lower conductive pattern DCP1. Further, the spacer 348 can also be disposed between the planarization layer 146 and the second lower conductive pattern DCP2. Further, the spacer 348 can also be disposed between the planarization layer 146 and the third lower conductive pattern DCP3. Further, the spacer 348 can also be disposed between the planarization layer 146 and the fourth lower conductive pattern DCP4. For example, the spacer 348 can be in contact with a bottom surface of each of the first lower conductive pattern DCP1, the second lower conductive pattern DCP2, the third lower conductive pattern DCP3, and the fourth lower conductive pattern DCP4. The spacer 348 is formed on a top surface of the planarization layer 146.

The above-described spacer 348 can serve to maintain an interval between the first lower conductive pattern DCP1, the second lower conductive pattern DCP2, the third lower conductive pattern DCP3, and the fourth lower conductive pattern DCP4 and the planarization layer 146.

A first contact hole which connects the first lower conductive pattern DCP1 and the first pad PD1 can be formed to pass through the spacer 348 disposed between the planarization layer 146 and the first lower conductive pattern DCP1. A second contact hole which connects the second lower conductive pattern DCP2 and the second pad PD2 can be formed to pass through the spacer 348 disposed between the planarization layer 146 and the second lower conductive pattern DCP2. A third contact hole which connects the third lower conductive pattern DCP3 and the third pad PD3 can be formed to pass through the spacer 348 disposed between the planarization layer 146 and the third lower conductive pattern DCP3.

A low potential voltage for driving the light emitting diodes 170R, 170B, and 170G can be applied to the fourth lower conductive pattern DCP4 and the fourth upper connection line 381b-4. For example, the plurality of lower conductive patterns DCP1, DCP2, DCP3, and DCP4 and the plurality of upper connection lines 381b-1, 381b-2, 381b-3, and 381b-4 configure a conductive surface to which one low potential voltage is applied.

Therefore, when the display device 300 is on, the driving voltage is applied to the first electrode 171 by means of the connection pad CNT and the low potential voltage is applied to the second electrode by means of the fourth lower conductive pattern DCP4. Therefore, different voltage levels are transmitted to the first electrode 171 and the second electrode 175 to allow the light emitting diodes 170R, 170B, and 170G to emit light.

As described above, the display device 300 according to still another exemplary embodiment of the present disclosure applies not only a low potential voltage, but also a high potential voltage and a gate voltage, through the plurality of upper connection lines 381b-1, 381b-2, 381b-3, and 381b-4 disposed on the upper substrate 112.

Therefore, in the display device according to still another exemplary embodiment of the present disclosure, a connection line for applying the high potential voltage and the gate voltage can be removed from the lower substrate 111.

Accordingly, a number of connection lines on the lower substrate 111 is reduced so that a resistance for stretching the display device can be improved. As a result, a stretching rate of the display device 300 according to another exemplary embodiment of the present disclosure can be improved.

Further, the display device 300 according to still another exemplary embodiment of the present disclosure includes not only the lower conductive patterns DCP1, DCP2, DCP3, and DCP4, but also the upper conductive patterns UCP1 and UCP2. Some of the lower conductive patterns DCP1, DCP2, DCP3, and DCP4 and the upper conductive patterns UCP1 and UCP2 are electrically connected.

Specifically, the first upper conductive pattern UCP1 is electrically connected to the first lower conductive pattern DCP1 through a contact hole and the second upper conductive pattern UCP2 is electrically connected to the second lower conductive pattern DCP2 through a contact hole.

Therefore, a total resistance of the first upper conductive pattern UCP1 and the first lower conductive pattern DCP1 is reduced and a total resistance of the second upper conductive pattern UCP2 and the second lower conductive pattern DCP2 is reduced. As a result, the drop of the high potential voltage which is applied to the first upper conductive pattern UCP1 and the first lower conductive pattern DCP1 can be minimized. Further, the delay of the gate voltage which is applied to the second lower conductive pattern DCP2 through the contact hole is also minimized.

The exemplary embodiments of the present disclosure can also be described as follows:

According to an aspect of the present disclosure, a display device includes a lower substrate which is stretchable; a plurality of pixels disposed on the lower substrate; a plurality of lower connection lines which is disposed on the lower substrate and is connected to each of the plurality of pixels; an upper substrate which is opposite to the lower substrate and is stretchable; a plurality of conductive patterns which is disposed below the upper substrate and is connected to the plurality of pixels, respectively; and a plurality of upper connection lines which is disposed below the upper substrate and is connected to the plurality of conductive patterns. By doing this, the dropping of a driving voltage can be minimized.

A total area of the upper connection line and conductive pattern may be greater than an area of the lower connection line.

A plurality of lower plate patterns can be disposed between the lower substrate and the plurality of pixels, a plurality of lower line patterns can be disposed between the lower substrate and the plurality of lower connection lines, and a modulus of elasticity of each of the plurality of lower plate patterns and the plurality of lower line patterns can be higher than a modulus of elasticity of the lower substrate.

A plurality of upper plate patterns can be disposed between the upper substrate and the plurality of conductive patterns, a plurality of upper line patterns can be disposed between the upper substrate and the plurality of upper connection lines, and a modulus of elasticity of each of the plurality of upper plate patterns and the plurality of upper line patterns can be higher than a modulus of elasticity of the upper substrate.

Each of the plurality of pixels can include a vertical light emitting diode which is electrically connected to any one of the plurality of conductive patterns.

Only a first driving voltage can be applied to the plurality of conductive patterns.

Only the first driving voltage can be applied to the plurality of upper connection lines.

The plurality of upper connection lines can extend only in a first direction.

The plurality of lower connection lines can include a plurality of first lower connection lines extending in a first direction and a plurality of second lower connection lines extending in a second direction, a gate voltage and a second driving voltage can be applied to the plurality of first lower connection lines, and a data voltage can be applied to the plurality of second lower connection lines.

Each of the plurality of conductive patterns can include a first conductive pattern, a second conductive pattern, a third conductive pattern, and a fourth conductive pattern disposed on the same layer.

A width of the fourth conductive pattern may be greater than a width of any one of the first conductive pattern, the second conductive pattern, and the third conductive pattern.

Only a first driving voltage is applied to the fourth conductive pattern and a gate voltage or a second driving voltage can be applied to each of the first conductive pattern, the second conductive pattern, and the third conductive pattern.

The gate voltage and the second driving voltage are not applied to the fourth conductive pattern.

In each of the plurality of pixels, a first pad, a second pad, and a third pad are formed, the first conductive pattern can be electrically connected to the first pad through a first contact hole, the second conductive pattern can be electrically connected to the second pad through a second contact hole, the third conductive pattern can be electrically connected to the third pad through a third contact hole, and the fourth conductive pattern can be electrically connected to the vertical light emitting diode.

Each of the plurality of upper connection lines can include a first upper connection line, a second upper connection line, a third upper connection line, and a fourth upper connection line, the first upper connection line can connect the plurality of first conductive patterns, the second upper connection line can connect the plurality of second conductive patterns, the third upper connection line can connect the plurality of third conductive patterns, and the fourth upper connection line can connect the plurality of fourth conductive patterns.

The first upper connection line, the second upper connection line, the third upper connection line, and the fourth upper connection line can extend only in the first direction.

The first upper connection line, the second upper connection line, the third upper connection line, and the fourth upper connection line do not extend in a second direction which is different from the first direction.

The plurality of lower connection lines can extends only in the second direction and a data voltage is applied to the plurality of lower connection lines.

The plurality of lower connection lines do not extend in the first direction.

Each of the plurality of conductive patterns can include a first lower conductive pattern, a second lower conductive pattern, a third lower conductive pattern, and a fourth lower conductive pattern disposed on a first layer and a first upper conductive pattern and a second upper conductive pattern disposed on a second layer, the first lower conductive pattern can be electrically connected to the first upper conductive pattern, and the second lower conductive pattern can be electrically connected to the second upper conductive pattern.

The first lower conductive pattern may be electrically connected to the first upper conductive pattern through a contact hole in an insulating layer, and the second lower conductive pattern may be electrically connected to the second upper conductive pattern through a contact hole in the insulating layer.

A width of the fourth lower conductive pattern may be greater than a width of any one of the first lower conductive pattern, the second lower conductive pattern, and the third lower conductive pattern.

Only a first driving voltage can be applied to the fourth lower conductive pattern and a gate voltage or a second driving voltage can be applied to each of the first lower conductive pattern, the second lower conductive pattern, and the third lower conductive pattern.

The gate voltage and the second driving voltage are not applied to the fourth lower conductive pattern.

In each of the plurality of pixels, a first pad, a second pad, and a third pad are formed, the first lower conductive pattern can be electrically connected to the first pad through a first contact hole, the second lower conductive pattern is electrically connected to the second pad through a second contact hole, the third lower conductive pattern can be electrically connected to the third pad through a third contact hole, and the fourth lower conductive pattern can be electrically connected to the vertical light emitting diode.

Each of the plurality of upper connection lines can include a first upper connection line and a second upper connection line disposed on the second layer and a third upper connection line and a fourth upper connection line disposed on the first layer, the first upper connection line can connect a plurality of first upper conductive patterns, the second upper connection line can connect a plurality of second upper conductive patterns, the third upper connection line connects a plurality of third lower conductive patterns, and the fourth upper connection line connects a plurality of fourth lower conductive patterns.

The first upper connection line, the second upper connection line, the third upper connection line, and the fourth upper connection line can extend only in the first direction.

The first upper connection line, the second upper connection line, the third upper connection line, and the fourth upper connection line do not extend in a second direction which is different from the first direction.

The plurality of lower connection lines can extend only in the second direction and a data voltage is applied to the plurality of lower connection lines.

The plurality of lower connection lines do not extend in the first direction.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a lower substrate which is stretchable;
a plurality of pixels disposed on the lower substrate;
a plurality of lower connection lines disposed on the lower substrate and connected to each of the plurality of pixels;
an upper substrate which is stretchable, and disposed opposite to the lower substrate;
a plurality of conductive patterns disposed below the upper substrate and connected to the plurality of pixels, respectively; and
a plurality of upper connection lines disposed below the upper substrate and connected to the plurality of conductive patterns.

2. The display device according to claim 1,
wherein a plurality of lower plate patterns is disposed between the lower substrate and the plurality of pixels,
a plurality of lower line patterns is disposed between the lower substrate and the plurality of lower connection lines, and
a modulus of elasticity of each of the plurality of lower plate patterns and the plurality of lower line patterns is higher than a modulus of elasticity of the lower substrate.

3. The display device according to claim 1,
wherein a plurality of upper plate patterns is disposed between the upper substrate and the plurality of conductive patterns,
a plurality of upper line patterns is disposed between the upper substrate and the plurality of upper connection lines, and
a modulus of elasticity of each of the plurality of upper plate patterns and the plurality of upper line patterns is higher than a modulus of elasticity of the upper substrate.

4. The display device according to claim 1,
wherein each of the plurality of pixels includes a vertical light emitting diode electrically connected to one of the plurality of conductive patterns.

5. The display device according to claim 4,
wherein only a first driving voltage is applied to the plurality of conductive patterns.

6. The display device according to claim 5,
wherein only the first driving voltage is applied to the plurality of upper connection lines.

7. The display device according to claim 5,
wherein the plurality of upper connection lines extends only in a first direction.

8. The display device according to claim 5,
wherein the plurality of lower connection lines includes a plurality of first lower connection lines extending in a first direction,
a plurality of second lower connection lines extending in a second direction different from the first direction,
a gate voltage and a second driving voltage are applied to the plurality of first lower connection lines, and
a data voltage is applied to the plurality of second lower connection lines.

9. The display device according to claim 4,
wherein each of the plurality of conductive patterns includes a first conductive pattern, a second conductive pattern, a third conductive pattern, and a fourth conductive pattern disposed on a same layer.

10. The display device according to claim 9,
wherein only a first driving voltage is applied to the fourth conductive pattern, and
a gate voltage or a second driving voltage is applied to each of the first conductive pattern, the second conductive pattern, and the third conductive pattern.

11. The display device according to claim 9,
wherein in each of the plurality of pixels, a first pad, a second pad, and a third pad are formed,
the first conductive pattern is electrically connected to the first pad through a first contact hole,
the second conductive pattern is electrically connected to the second pad through a second contact hole,
the third conductive pattern is electrically connected to the third pad through a third contact hole, and
the fourth conductive pattern is electrically connected to the vertical light emitting diode.

12. The display device according to claim 9,
wherein each of the plurality of upper connection lines includes a first upper connection line, a second upper connection line, a third upper connection line, and a fourth upper connection line,
the first upper connection line connects the plurality of first conductive patterns,
the second upper connection line connects the plurality of second conductive patterns,
the third upper connection line connects the plurality of third conductive patterns, and
the fourth upper connection line connects the plurality of fourth conductive patterns.

13. The display device according to claim 12,
wherein the first upper connection line, the second upper connection line, the third upper connection line, and the fourth upper connection line extend only in a first direction.

14. The display device according to claim 13,
wherein the plurality of lower connection lines extends only in a second direction different from the first direction, and
a data voltage is applied to the plurality of lower connection lines.

15. The display device according to claim 4,
wherein each of the plurality of conductive patterns includes a first lower conductive pattern, a second lower conductive pattern, a third lower conductive pattern, and a fourth lower conductive pattern disposed on a first layer, and a first upper conductive pattern and a second upper conductive pattern disposed on a second layer,
the first lower conductive pattern is electrically connected to the first upper conductive pattern, and
the second lower conductive pattern is electrically connected to the second upper conductive pattern.

16. The display device according to claim 15,
wherein only a first driving voltage is applied to the fourth lower conductive pattern, and
a gate voltage or a second driving voltage is applied to each of the first lower conductive pattern, the second lower conductive pattern, and the third lower conductive pattern.

17. The display device according to claim 15,
wherein in each of the plurality of pixels, a first pad, a second pad, and a third pad are formed,
the first lower conductive pattern is electrically connected to the first pad through a first contact hole,
the second lower conductive pattern is electrically connected to the second pad through a second contact hole,
the third lower conductive pattern is electrically connected to the third pad through a third contact hole, and
the fourth lower conductive pattern is electrically connected to the vertical light emitting diode.

18. The display device according to claim 15,
wherein each of the plurality of upper connection lines includes a first upper connection line and a second upper connection line disposed on the second layer, and a third upper connection line and a fourth upper connection line disposed on the first layer,
the first upper connection line connects a plurality of first upper conductive patterns,
the second upper connection line connects a plurality of second upper conductive patterns,
the third upper connection line connects a plurality of third lower conductive patterns, and
the fourth upper connection line connects a plurality of fourth lower conductive patterns.

19. The display device according to claim 18,
wherein the first upper connection line, the second upper connection line, the third upper connection line, and the fourth upper connection line extend only in the first direction.

20. The display device according to claim 19,
wherein the plurality of lower connection lines extends only in the second direction, and
a data voltage is applied to the plurality of lower connection lines.
